(19) United States
(12) Patent Application Publication
(10) Pub. No.: US 2026/0150190 A1
(43) Pub. Date: May 28, 2026

(54) ASSEMBLY WITH AN ELECTRIC FEEDTHROUGH AND METHOD FOR THE PRODUCTION THEREOF

(71) Applicant: SCHOTT AG, Mainz (DE)

(72) Inventors: Johannes RÖHRL, Landshut (DE); Lukas GROHMANN, Landshut (DE); Christoph ZOBEL, Landshut (DE); Daniela WASTL, Landshut (DE); Sabine SCHMIDBAUER, Landshut (DE); Phillip SCHERZL, Landshut (DE); Johannes LAINER, Landshut (DE)

(73) Assignee: SCHOTT AG, Mainz (DE)

(21) Appl. No.: 19/396,881

(22) Filed: Nov. 21, 2025

(30) Foreign Application Priority Data
Nov. 27, 2024 (DE) 10 2024 134 966.2

(51) Int. Cl. H05K 1/09; H05K 1/11; H05K 3/24

(52) U.S. Cl. CPC H05K 1/09; H05K 1/115; H05K 3/244; H05K 2201/032; H05K 2201/0347; H05K 2201/09563; H05K 2203/072

(57) ABSTRACT

An assembly with an electric feedthrough is provided, including a main body having an opening, through which an electric conductor is passed and held with a fixing material. The electric conductor surface not covered by the fixing material has a first coating while the surface covered by the fixing material lacks the first coating. The main body surface uncovered by the fixing material omits the first coating and optionally has a second coating, different from the first coating, or is provided completely with the first coating. The main body surface covered by the fixing material lacks the first coating, and the electric conductor surface uncovered by the fixing material lacks the first coating and is optionally provided with a second coating, different from the first coating. The first coating has one or more layers, and the outermost layer is an electrolessly deposited layer of a first coating material.

### CROSS REFERENCE TO RELATED APPLICATIONS

This application claims the benefit of priority from German Patent Application No. 10 2024 134 966.2, filed Nov. 27, 2024, the contents of which are incorporated herein by reference.

### FIELD OF THE INVENTION

The invention relates to an assembly with at least one electric feedthrough comprising a main body having at least one opening, through which an electric conductor is passed and is held in the opening by means of a fixing material in a manner electrically insulated from the main body, wherein the fixing material closes the opening. In this case, the electric conductor and/or the main body are/is provided with a coating. The invention furthermore relates to a method for producing such an assembly.

### BACKGROUND OF THE INVENTION

Assemblies with an electric feedthrough are used in various areas, e.g. in igniters for airbags, in housings for electronic or optoelectronic components, and in electrically driven compressors. In this case, the assemblies can contain one or more electric feedthroughs, wherein an electric feedthrough comprises a main body and an electric conductor passed through an opening in the main body. In this case, the electric conductor is held in the opening by means of an electrically insulating fixing material, and the opening is sealed leaktightly by means of the fixing material. Electric feedthroughs of this kind are also referred to as fixing-material/metal feedthroughs.

Typical fixing-material/metal feedthroughs are constructed in such a way that electric conductors, in particular metal pins or terminal pins, are fused into a pre-moulded preform, wherein the preform is inserted together with the conductor into the main body. The fixing material is obtained from the preform by a temperature treatment.

A fixing-material/metal feedthrough of this kind for use in igniters for airbags is known from DE 10 2014 219 124 A1. To avoid oxidation or to functionalize the surface of the electric conductors passed through, provision is made to coat them with gold by electroplating processes.

In the case of electroplating, the components to be coated, in this case the electric conductors of the electric feedthrough, are electrically contacted and dipped into a coating solution. By controlling the current intensity and duration it is possible to adjust the thickness of the coating obtained. The main body, which is electrically insulated from the conductors by the fixing material, is not coated during this process.

The disadvantage with the known electroplating process is that the electric feedthrough conductors to be coated must each be electrically contacted individually, making the method slow and complicated. Moreover, a defect in the coating usually occurs at the contact point at which the electric conductor is electrically contacted, and this defect can become a starting point for corrosion.

It is thus an object of the invention to provide an assembly in which selectively only selected components are coated, wherein the coating thereof is free from defects and wherein the coating can be produced easily and without electric contacting of the individual electric conductors.

### SUMMARY OF THE INVENTION

The proposal is for an assembly, wherein the assembly has at least one electric feedthrough, comprising a main body having an opening, through which an electric conductor is passed and is held in the opening by means of a fixing material in a manner electrically insulated from the main body, wherein the fixing material closes the opening and wherein both the electric conductor and the base body are metallic components. The surface of the electric conductor which is not covered by the fixing material is provided completely with a first coating, the surface of the electric conductor which is covered by the fixing material is free from the first coating, and the surface of the main body which is not covered by the fixing material is free from the first coating and is optionally provided with a second coating, which is different from the first coating, or
the surface of the main body which is not covered by the fixing material is provided completely with the first coating, the surface of the main body which is covered by the fixing material is free from the first coating, and the surface of the electric conductor which is not covered by the fixing material is free from the first coating and is optionally provided with a second coating, which is different from the first coating.

It is furthermore envisaged that the first coating has one or more layers, and at least an outermost layer of the first coating is an electrolessly deposited layer of a first coating material. If the first coating has only a single layer, this is also the outermost layer.

The electric feedthrough thus has at least two metallic components, an electric conductor and a main body, wherein, after the formation of the electric feedthrough, in which the electric conductor is passed through an opening in the main body and held by means of a fixing material, the first coating was applied selectively only to one of the two components. The other component in each case remains free from the first coating.

The electrolessly deposited outermost layer of the first coating is obtained by dipping an unfinished assembly comprising the at least one electric feedthrough into a bath containing a coating solution, in particular an electrolyte solution. Without an external supply of current, the first coating material is deposited selectively from the bath on the surface of the electric conductor or main body which is not covered by the fixing material and is therefore exposed, wherein the surface of the other component in each case remains free from the first coating material. For this selective deposition, the metal materials of the main body and of the electric conductor or the material of the surfaces thereof are/is selected in such a way that only one of these components is coated during the electroless deposition, and the respective other component remains uncoated.

The assembly can comprise more than one electric feedthrough, wherein several electric feedthroughs can share a common main body. The electric feedthrough is preferably designed as a fixing-material/metal feedthrough. Such a fixing-material/metal feedthrough can be obtained, for example, by providing a fixing material blank, e.g. in the form of a tubular section consisting of a glass or a preform consisting of a glass powder, and inserting it together with the electric conductor into an opening in the main body. The fixing material blank is melted by a temperature treatment and forms the fixing material. During this process, the fixing material forms a seal with respect to the wall of the opening and the electric conductor. The first coating is applied after the formation of the electric feedthrough and, accordingly, covers only the surfaces of the electric conductor or main body which are not covered by the fixing material.

The later application of the first coating makes it possible to select materials for the first coating which are not resistant to the high temperatures involved in the formation of the electric feedthrough. Such coating materials may melt or, at the elevated temperatures, there may be (inter)diffusion with underlying materials or with the material of the electric conductor or main body. As a result, the coating may fail to perform its function. One example of this are gold layers intended to improve an electric contact with the electric conductor or to provide protection from oxidation.

Here, the selectivity of the electroless coating method used is exploited to provide only selected parts or components of the assembly with the first coating or the outermost layer of the first coating. This is advantageous in the case of a gold coating, for example, which can serve to provide protection against oxidation and to improve an electric connection between an electric contact and the electric conductor, for example. On the one hand, there is a saving of material and, on the other hand, the component that is not coated retains its properties.

One feature of electroless deposition is the high degree of uniformity in the layer thickness obtained in the deposited layer and the possibility of fully coating the surface of the respective component that is not covered by the fixing material, since there are no defects due to electric contacting. In contrast, the local layer thickness in the case of electrodeposition depends on the local electric field strength and the locally available cathodic current density, which is not uniform but is affected, in particular, by the geometry and orientation of the component in the electrolyte. At points on the component which have a marked curvature or corners or edges, the local current intensity depends on whether the curvature is convex or concave, increased or reduced, and this is reflected in a corresponding variation in the thickness of the coating. Thus, for example, in the region of external edges, e.g. at the ends of the conductors, the electric field strength or current density is locally increased, and therefore more material is deposited there during electroplating than in regions in which the surface is flatter. Accordingly, electroplated conductors generally have a greater layer thickness at their ends than, for example, in the regions at a distance from the end. Moreover, electroplated conductors or main bodies have at least one defect in the coating, where the component was electrically contacted for electrodeposition. In contrast, an electrolessly deposited coating does not have such a defect. The coating formed can be complete and continuous, although, in the case of thin layers with thicknesses in the range of a few tens of nanometres to a few micrometres, pores cannot be completely avoided and, within the context of this description, layers with such small pores are also still regarded as complete, continuous layers.

Here, electroless deposition is divided into two groups: deposition by ion or charge exchange (cementation, immersion deposition; the substrate itself is the reducing agent), and autocatalytic deposition (chemical deposition; the reducing agent is contained in the coating solution). Materials with an autocatalysing action initiate the deposition of the layer themselves (in the case of nickel as the material to be deposited, these are, for example, Co, Ni, Ru, Rh, Pd, Os, Ir and Pt). Materials that involve an external catalysing action do not themselves act as catalysts and become catalytically active only through nucleation by a material with an autocatalysing action. In the case of the materials which are less noble in the electrolyte solution than the material to be deposited, nuclei of the material to be deposited are initially deposited by means of cementation. In the case of a nickel coating, Ni nuclei are initially deposited by charge exchange (cementation). In the case of nickel as the material to be deposited, these less noble materials include Be or Fe, for example. It is thereby possible to electrolessly coat these materials too.

Here, cementation refers, in particular, to the fact that nuclei which are catalytically active are applied to the surface to be coated before the coating process or at the start of the coating process. Materials in the electrolyte solution which are nobler than the material to be deposited and do not have an autocatalysing action and thus, in the case of nickel, do not act catalytically by means of the cementation of Ni nuclei can be made catalytically active by means, for example, of a short cathodic current pulse in the coating solution and the associated deposition of Ni nuclei, the deposition of a nickel strike layer, or the application of other catalytically active nuclei on the surface.

The electric conductor provided with the first coating, or the main body provided with the first coating, consists completely or at least on the surface thereof of a first metal material which can be coated electrolessly with the first coating material, or has an intermediate layer which consists of the first metal material which can be coated electrolessly with the first coating material. Given a suitable choice of material, this intermediate layer can likewise be deposited electrolessly or, as an alternative, can have been produced by some other coating method.

The first metal material is preferably selected so that its surface is catalytically active for electroless deposition or is made catalytically active by the application of catalytically active nuclei. Preferred examples of suitable first metal materials are Ag, Ag alloys, Cu, Cu alloys, Ni, Ni alloys without a passive layer, platinum metals and platinum metal alloys, Fe, steels without a passive layer, Co and Co alloys without a passive layer, Kovar, Mn and Mn alloys without a passive layer, Zn, Zn alloys, Sn and Sn alloys.

Here, a passive layer is understood to mean, in particular, an oxide layer which forms on the surface of the respective material and prevents electroless deposition and is thus passive in relation to the electroless deposition of the first coating material. In the case of stainless steels, chromium and oxygen on the surface of the material, for example, form a chromium oxide layer which is passive in relation to electroless coating and therefore cannot be coated with the first coating material. If materials that form such passive layers are to be coated, the passive layer must be removed before electroless coating, ensuring that the surface is free from such a passive layer or oxide layer.

The main body, which is free from the first coating, or the electric conductor, which is free from the first coating, consists completely or at least on the surface thereof of a second metal material which cannot be coated electrolessly with the first coating material, or has a second coating, the single or outermost layer of which consists of the second metal material which cannot be coated electrolessly with the first coating material.

Accordingly, the second metal material is selected so that the surface thereof is passive in relation to the coating solution. Preferred examples of suitable second metal materials are stainless steels with a passive layer, e.g. a chromium oxide layer, nickel alloys with a passive layer, in particular nickel alloys containing Mo, Cu and/or Cr. The metals Ti, Mo, W, Al, Nb, Cr, Zr, Hf, V, Ta and their alloys are also suitable.

In the case of a metal material which forms a passive layer, this passive layer can be interpreted as a kind of second coating. Since this passive layer naturally forms on these metal materials, this passive layer is regarded for the sake of simplicity as part of the second metal material in the context of this description.

The first coating material is preferably selected from the group comprising nickel containing proportions of phosphorus (NiP), nickel containing proportions of boron (NiB), Ni, Cu, Sn, Ag, palladium containing proportions of phosphorus (PdP), Pd, and Au.

Chemical deposition of nickel can take place, for example, in the form of a nickel-phosphorus or a nickel-boron layer. In both cases, the assembly is dipped into an aqueous coating solution containing, inter alia, a nickel salt and a reducing agent. In the case of a nickel-phosphorus coating, a phosphinate is used as the reducing agent, for example, while, in the case of a nickel-boron layer, a boron hydride is usually used. The coating process takes place with autocatalysis, and accordingly only those surfaces are coated with nickel or the corresponding nickel alloy which are catalytically active or have been made catalytically active by means of cementation, for example.

Electroless deposition of copper (Cu) can likewise be performed chemically. A prerequisite for deposition is a first metal material which has an autocatalytic action or which is less noble than Cu. In the latter case, Cu nucleation initially takes place by cementation.

Electroless deposition of silver (Ag) can take place chemically or by means of cementation (immersion deposition, immersion silver). A prerequisite for chemical deposition is a first metal material which has an autocatalytic action or which is less noble than Ag. In the latter case, Ag nucleation initially takes place by cementation.

Electroless deposition of tin (Sn) can likewise take place chemically or by means of cementation. A prerequisite for deposition is a first metal material which has an autocatalytic action or which is less noble than Sn.

Electroless deposition of palladium can take place chemically, e.g. as a palladium-phosphorus layer, and by means of cementation (immersion deposition, immersion palladium). A prerequisite for deposition is a first metal material which has an autocatalytic action or which is less noble than Pd. In the latter case, Pd nucleation initially takes place by cementation.

Electroless deposition of gold (Au) can take place chemically (autocatalytically), by means of cementation (immersion deposition, immersion gold) and also semi-autocatalytically. A prerequisite for chemical deposition is a first metal material which has an autocatalytic action or which is less noble than Au. In the latter case, Au nucleation initially takes place by cementation. Semi-autocatalytic deposition represents a hybrid form of pure immersion and autocatalytic deposition. By means of this method, in the case of a chemical nickel/immersion gold layer system, for example, the corrosive attack on the underlying chemical nickel layer inherent in the immersion deposition method is reduced by the proportionate autocatalytic reaction mechanism.

The first coating preferably comprises a plurality of layers. In this case, a nickel layer, e.g. a nickel-phosphorus layer, is preferably used as the first layer. The nickel layer is such that further layers of the coating can be deposited by means of electroless processes. The nickel layer can serve as a means of corrosion protection.

In one example, precisely two layers are used, wherein the first layer is a nickel layer or nickel alloy layer, and the second layer is a gold layer. This combination of layers is advantageous as a contact surface for soldering and can be used, for example, for aluminium wire bonding.

In another example, precisely three layers are used, wherein the first layer is a nickel layer or nickel alloy layer, the second layer is a palladium layer or palladium alloy layer, and the third layer is a gold layer. This combination of layers is advantageous as a contact surface for soldering and can be used, for example, for gold wire bonding.

All the electric conductors are preferably selected from the same metal material, or the surfaces thereof are selected from the same metal material, and therefore all the electric conductors are either capable of being coated electrolessly or not capable of being coated electrolessly. As an alternative, it is conceivable to select one or more electric conductors from some other metal material or to select the surface thereof from some other metal material which cannot be coated electrolessly. It is thereby possible to ensure in a selective way that only selected electric conductors are provided with the first coating and other, unselected electric conductors remain free from the first coating.

The material of the main body which cannot be coated electrolessly is preferably an austenitic stainless steel. In this case, there is a passive layer on the surface of the stainless steel, and this layer cannot be coated electrolessly with the first coating material.

An iron-nickel alloy, such as NiFe45, is suitable, in particular, as a material for the electrolessly coatable electric conductor. Other well-suited materials for an electrolessly coatable conductor include nickel-cobalt alloys, such as NiCo2918, wires with a core made of copper and a sheath made of a nickel-iron alloy.

The fixing material is preferably selected from a group comprising a glass, a glass ceramic or a ceramic. To form a preform or a fixing material blank, the starting material can be moulded in powder form together with a binder to give a fixing material blank. However, the fixing material blank may also be supplied as a tube section, for example.

The fixing-material/metal feedthrough formed is preferably of hermetically sealed design. In this context, hermetically sealed is taken to refer to a feedthrough which has a helium leakage rate of less than 1·10⁻⁸ mbar·l/s.

The assembly can additionally comprise one or more earth conductors. Such an earth conductor is connected in an electrically conductive manner to the main body and secured on the latter, e.g. by means of soldering or welding.

Depending on the embodiment, the earth conductor can consist of a metal material at its surface or can comprise a metal material at its surface which can be coated electrolessly or cannot be coated electrolessly. A metal material that can be coated electrolessly is preferably selected if the metal material of the main body is also a material which can be coated electrolessly and, conversely, a metal material which cannot be coated electrolessly is preferably selected if the metal material of the main body likewise cannot be coated electrolessly.

Another aspect of the invention is to provide a method for producing the assemblies described herein.

In a first step of the method, an electric conductor which has a first metal material on its surface or which consists of the first metal material is supplied and a main body having an opening which has a second metal material on its surface or consists of the second metal material is supplied. Alternatively, a main body having an opening which has a first metal material on its surface or consists of the first metal material is supplied, and an electric conductor which has a second metal material on its surface or consists of the second metal material is supplied. A fixing material blank is furthermore supplied.

Following this, the electric conductor and the fixing material blank are inserted into the opening in the main body. The electric conductor is then embedded and the fixing material is formed by means of a temperature treatment. During this process, an electric feedthrough is formed, and an unfinished assembly is obtained.

After the unfinished assembly has been obtained, a layer of a first coating material is deposited electrolessly on exposed surfaces of the electric conductor or on exposed surfaces of the main body by dipping the unfinished assembly into a coating solution. If required, the unfinished assembly can be pretreated before the electroless coating. This can comprise cleaning the surfaces.

As an option, the coating step can be repeated by dipping the unfinished assembly into one or more further coating solutions, with the result that the first coating obtained by means of the coating step or steps comprises one or more layers. Here, the respective layer of the first coating which is obtained last is the outermost layer.

### EXAMPLE

First of all, an unfinished assembly with an electric feedthrough was produced. To produce the unfinished assembly, a main body consisting of an austenitic stainless steel with the material number 1.4404 and an electric conductor consisting of NiFe45 was used. To form the fixing material, a glass preform was used as a fixing material blank. The electric conductor and the glass preform were inserted into an opening in the main body and fused in a furnace.

First of all, the surfaces of the unfinished assembly were cleaned in order to remove grease and to remove oxides from the surface of the electric conductor, which would form a passive layer.

The unfinished assembly was then inserted into an electrolessly depositing nickel electrolyte in order to deposit a nickel-phosphorus layer. After obtaining the desired layer thickness, the unfinished assembly was rinsed in a water bath and inserted into a bath containing an immersion gold electrolyte.

Appropriate selection of the metal materials for the electric conductor and the main body gave assemblies in which only the electric conductors were selectively provided with a two-layer coating that had an intermediate layer consisting of nickel-phosphorus and an outermost layer consisting of gold.

In the selective electroless coating process proposed, the individual electric conductors of the assemblies advantageously do not have to be brought into contact with an electric connection to enable them to be electroplated. The individual unfinished assemblies can simply be inserted into the coating solution or electrolyte and their electric conductors can be coated in a targeted way. This allows quick and simple coating of a large number of assemblies. In addition, the proposed electroless coating has the advantage that the layer thicknesses achieved are uniform and, in particular, the layer thickness is not greater at the ends of the conductors. Moreover, the electrolessly deposited coating does not have any defects of the kind that usually occur at the point of contact with the electric connection. Such defects should be avoided in order, for example, to avoid corrosion. In addition, the method is selective, with the result that the main body remains free from the coating and therefore the properties of the material of the main body are maintained.

The invention will be described in greater detail below with reference to the figures and without being restricted thereto. Here, the same reference signs denote identical or similar elements.

### BRIEF DESCRIPTION OF THE DRAWINGS

In the drawings:

FIG. 1: shows an assembly with three electric feedthroughs, in which the conductors are selectively coated,

FIG. 2: shows an assembly with three electric feedthroughs, in which the main body is selectively coated,

FIG. 3: shows an assembly with three electric feedthroughs, in which both the main body and the conductors are selectively coated,

FIG. 4 shows an assembly with one feedthrough and a selectively coated conductor,

FIG. 5 shows an assembly with one electric feedthrough and a selectively coated conductor, and

FIG. 6 shows an assembly with one electric feedthrough and a selectively coated conductor and an additional earth conductor.

### DETAILED DESCRIPTION OF THE INVENTION

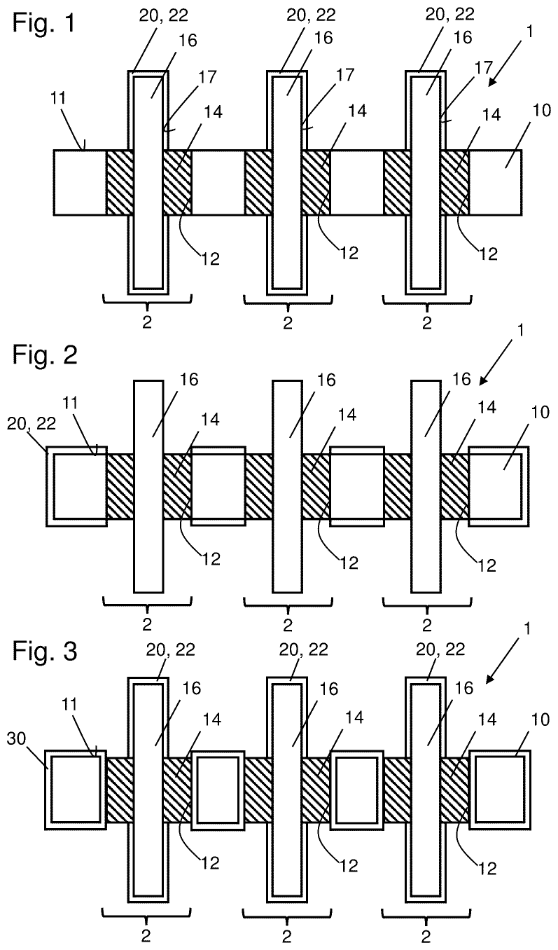

FIG. 1 shows a first example of an assembly 1 with, in this example, three electric feedthroughs 2 in a schematic sectional illustration from the side. The electric feedthroughs 2 have a common main body 10, which has an opening 12 for each of the electric feedthroughs 2. An electric conductor 16 is passed through each of the openings 12. The conductors 16 are each embedded in a fixing material 14, which holds the respective conductor 16 and insulates it electrically from the main body 10.

In the example illustrated in FIG. 1, the surface 17 of the conductors 16 that is not covered by the fixing material 14 is provided with a first coating 20. This first coating 20 was applied selectively to the conductors 16 after the formation of the electric feedthroughs 2. Accordingly, that part of the surface of the conductors 16 which is covered by the fixing material 14 is free from the first coating 20. Since the first coating 20 was applied selectively, only the material of the conductors 16 was coated. Accordingly, the surface 11 of the main body 10 is free from the first coating 20.

In the example depicted in FIG. 1, the first coating 20 has a single layer, which is therefore also the outermost layer 22. This outermost layer 22 was applied electrolessly to the surface 17 of the conductors 16. Owing to the electroless coating, the coating 20 or outermost layer 22 of the first coating 20 does not exhibit any increase in the layer thickness at edges, such as the ends of the conductors 16, over the entire coated surface of the conductors 16. Since, in addition, there is no need for an electrical connection for electroplating, the first coating 20 is furthermore completely continuous and advantageously has no defects.

In the example depicted, the first coating 20 or outermost layer 22 is a nickel-phosphorus layer or gold layer, for example. For the electroless coating of the surface 17 of the conductors 16, the material of the conductors 16 was selected so that they can be coated electrolessly. In the example depicted, the conductors 16 consist of NiFe45.

In contrast, the surface 11 of the main body 10 is free from the first coating 20 since the material of the main body 10 was selected so that it cannot be coated electrolessly. In the example depicted, the main body 10 consists of a stainless steel which forms a passive layer on its surface and, accordingly, cannot be coated electrolessly with the nickel-phosphor layer or gold layer.

In the example shown in FIG. 1, all three electric conductors 16 consist of the same material, which can be coated electrolessly. As an alternative, it is conceivable to select one or more conductors 16 from some other material which cannot be coated electrolessly, or to provide them with a second coating 30, cf. FIG. 3, which cannot be coated electrolessly. It is thereby possible to ensure in a selective way that only selected conductors 16 are provided with the first coating 20 and other, unselected conductors 16 remain free from the first coating 20.

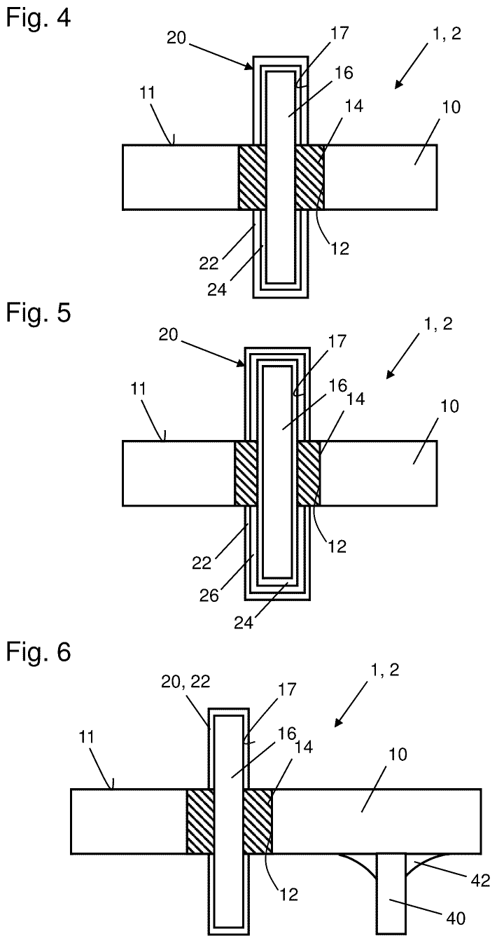

In the example depicted, the first coating 20 has only a single layer, which is accordingly also the outermost layer 22. By repeating the coating process with different coating solutions, additional layers can be applied. In the example described below with reference to FIG. 4, the first coating 20 has two layers. An intermediate layer 24 is additionally arranged below the outermost layer 22. In the example described below with reference to FIG. 5, the first coating 20 has three layers. Starting from the outermost layer 22, the outermost layer 22, an additional intermediate layer 26 and an intermediate layer 24 are arranged in this sequence. In additional embodiments, it would furthermore be conceivable to provide more than three layers, e.g. four or five layers.

FIG. 2 shows a second example of an assembly 1 with, in this example, three electric feedthroughs 2 in a schematic sectional illustration from the side. As already described with reference to FIG. 1, the electric feedthroughs 2 have a common main body 10, which has an opening 12 for each of the electric feedthroughs 2. An electric conductor 16 is passed through each of the openings 12. The conductors 16 are each embedded in a fixing material 14 which holds the respective conductor 16 and insulates it electrically from the main body 10.

In the example illustrated in FIG. 2, the surface 11 of the main body 10 that is not covered by the fixing material 14 is provided with a first coating 20. This first coating 20 was applied selectively to the main body 10 after the formation of the electric feedthroughs 2. Accordingly, that part of the surface of the main body 10 which is covered by the fixing material 14 is free from the first coating 20. Since the first coating 20 was applied selectively, only the material of the main body 10 was coated. Accordingly, the surface 17 of the conductors 16 is free from the first coating 20.

As in the example described with reference to FIG. 1, the first coating 20 has a single layer, the outermost layer 22, which was applied electrolessly to the surface 11 of the main body 10. Owing to the electroless coating, the first coating 20 or outermost layer 22 of the first coating 20 does not exhibit any increase in the layer thickness at edges over the entire coated surface of the main body 10. Since, in addition, there is no need for an electrical connection for electroplating, the first coating 20 is furthermore completely continuous and advantageously has no defects.

The outermost layer 22 of the first coating 20 can once again be a nickel-phosphorus layer, for example. In this example, the material selected for the main body was a steel which does not form a passive layer and accordingly can be coated electrolessly with the nickel-phosphorus layer. In contrast, the material of the conductors 16 is, for example, a stainless steel which forms a passive layer and thus cannot be coated electrolessly. Accordingly, the surface 17 of the conductors 16 is free from the first coating 20.

FIG. 3 shows schematically a third example of an assembly 1 with, in this example, three electric feedthroughs 2. The structure of the assembly 1 corresponds to the first example described with reference to FIG. 1. As a departure from the first example, the surface 11 of the main body 10 is not free from any coatings but is provided with a second coating 30, which is different from the first coating 20. In the example illustrated in FIG. 3, the second coating 30 was applied to the surface 11 of the main body 10 before the formation of the assembly 1, and therefore the second coating 30 covers the entire surface 11, including the part of the surface 11 of the main body 10 which adjoins the fixing material 14. Alternatively, however, it is also conceivable for the second coating 30 not to completely cover the surface 11 of the main body 10.

The second coating 30 can have one or more layers. In the example depicted in FIG. 3, the second coating 30 has precisely one layer, which accordingly also forms the outermost layer of the second coating 30. The second coating 30 or outermost layer of the second coating 30 consists of a second coating material, which is selected so that it cannot be coated electrolessly. In the case of the example shown in FIG. 3, it is accordingly possible for the main body 10 to consist of the same material as the electric conductors 16 or to consist of a first metal material which can be coated with the first coating material. However, selective coating remains possible since the material of the main body 10 is covered by the second coating 30.

FIG. 4 shows schematically a fourth example of an assembly 1 with, in this example, a single electric feedthrough 2. The electric feedthrough 2 has a main body 10 with an opening 12. A conductor 16 is passed through the opening 12 and embedded in a fixing material 14 which holds the conductor 16 and insulates it electrically from the main body 10.

In the example illustrated in FIG. 4, the first coating 20 has precisely two layers. Starting from the surface 17 of the conductor 16, the first coating 20 has an intermediate layer 24 and an outermost layer 22 in this sequence. Both layers, i.e. the intermediate layer 24 and the outermost layer 22, may have been deposited electrolessly. In the example depicted in FIG. 4, the intermediate layer 24 and the outermost layer 22 were both applied after the formation of the electric feedthrough 2, and therefore both layers cover only that part of the surface 17 of the conductor 16 which is not covered by the fixing material 14.

Moreover, it is conceivable that only the outermost layer 22 is deposited electrolessly, and the intermediate layer 24 is applied by means of some other method, that is to say, for example, by electroplating. If, in this case, the intermediate layer 24 is applied before the formation of the electric feedthrough 2, the intermediate layer 24, unlike the outermost layer 22, would cover the entire surface 17 of the conductor 16, that is to say also that part of the conductor 16 which is covered by the fixing material 14.

The intermediate layer 24 can be, for example, a nickel-phosphorus layer, and the outermost layer 22 can be a gold layer.

FIG. 5 shows schematically a fifth example of an assembly 1 with, in this example, a single electric feedthrough 2. The fifth example corresponds substantially to the fourth example described with reference to FIG. 4, but here the first coating 20 is embodied with precisely three layers. Starting from the surface 17 of the electric conductor 16, the first coating 20 has an intermediate layer 24, an additional intermediate layer 26 and an outermost layer 22.

The intermediate layer 24 can be a nickel layer, for example. The additional intermediate layer 26 can be a palladium layer, and the outermost layer 22 can be a gold layer.

In the example depicted in FIG. 5, the intermediate layer 24 was applied to the electric conductor 16 before the formation of the electric feedthrough 2 and therefore completely covers the electric conductor 16. After the formation of the electric feedthrough 2, an additional intermediate layer 26 was first applied and finally the outermost layer 22. The additional intermediate layer 26 and the outer layer 22 can both be deposited electrolessly. In particular, the intermediate layer 24 can be a nickel layer, which was applied by electroplating, for example.

In the example depicted in FIG. 5, the additional intermediate layer 26 and the outermost layer 22 were both deposited electrolessly. However, it is also conceivable that the additional intermediate layer 26 is applied by means of some other method, e.g. by means of an electroplating method, and only the outermost layer 22 is deposited electrolessly.

FIG. 6 shows schematically a sixth example of an assembly 1 with, in this example, a single electric feedthrough 2. The electric feedthrough 2 has a main body 10 with an opening 12. A conductor 16 is passed through the opening 12 and embedded in a fixing material 14 which holds the conductor 16 and insulates it electrically from the main body 10. In the example depicted in FIG. 6, the first coating 20 has precisely one layer, which is accordingly also the outermost layer 22.

In the example illustrated in FIG. 6, the assembly 1 has an earth conductor 40, which is connected in an electrically conductive manner to the main body 10, in addition to the electric conductor 16 of the electric feedthrough 2. The earth conductor 40 is connected using a solder material 42, for example. However, it is also conceivable to connect the earth conductor 40 to the main body 10 by some other method, e.g. by welding.

In the sixth example depicted, the earth conductor 40 consists of the same material as the main body 10 or consists of a material which differs therefrom but which likewise cannot be coated electrolessly. Accordingly, the earth conductor 40 and the main body 10 are free from the first coating 20 here.

Although the present invention has been described with reference to preferred exemplary embodiments, it is not restricted thereto but can be modified in a variety of ways.

### LIST OF REFERENCE SIGNS

1 assembly
2 electric feedthrough
10 main body
11 surface of main body
12 opening
14 fixing material
16 conductor
17 surface of conductor
20 first coating
22 outermost layer
24 intermediate layer
26 further intermediate layer
30 second coating
40 earth conductor
42 solder material

1. An assembly with at least one electric feedthrough, comprising a main body having an opening, through which an electric conductor is passed and is held in the opening by means of a fixing material in a manner electrically insulated from the main body, wherein the fixing material closes the opening, wherein both the electric conductor and the base body are metallic components and wherein
the surface of the electric conductor which is not covered by the fixing material is provided completely with a first coating, the surface of the electric conductor which is covered by the fixing material is free from the first coating, and the surface of the main body which is not covered by the fixing material is free from the first coating and is optionally provided with a second coating, which is different from the first coating, or
the surface of the main body which is not covered by the fixing material is provided completely with the first coating, the surface of the main body which is covered by the fixing material is free from the first coating, and the surface of the electric conductor which is not covered by the fixing material is free from the first coating and is optionally provided with a second coating, which is different from the first coating,
wherein the first coating has one or more layers, and at least an outermost layer of the first coating is an electrolessly deposited layer of a first coating material.

2. The assembly according to claim 1, wherein the outermost layer of the first coating has a layer thickness that is independent of the geometry of the coated component.

3. The assembly according to claim 2, wherein the layer thickness of the outermost layer is constant over the entire coated surface.

4. The assembly according to claim 1, wherein the electric conductor provided with the first coating, or the main body provided with the first coating, consists of a first metal material which can be coated electrolessly with the first coating material, or has an intermediate layer which consists of the first metal material which can be coated electrolessly with the first coating material.

5. The assembly according to claim 4, wherein the first metal material is selected from the group consisting of Ag, Ag alloys, Cu, Cu alloys, Ni, Ni alloys which are free from surface oxides that cannot be coated with the first coating material, platinum metals and platinum metal alloys, Fe, steels which are free from surface oxides that cannot be coated with the first coating material, Co and Co alloys which are free from surface oxides that cannot be coated with the first coating material, and Mn and Mn alloys which are free from surface oxides that cannot be coated with the first coating material, Zn, Zn alloys, Sn and Sn alloys.

6. The assembly according to claim 1, wherein the main body, which is free from the first coating, or the electric conductor, which is free from the first coating, consists of a second metal material which cannot be coated electrolessly with the first coating material, or the second coating has an outermost layer consisting of the second metal material which cannot be coated electrolessly with the first coating material.

7. The assembly according to claim 6, wherein the second metal material is selected from the group consisting of steels with formed surface oxides that cannot be coated with the first coating material, nickel alloys with formed surface oxides that cannot be coated with the first coating material.

8. The assembly according to claim 7, wherein the second metal material is selected from the group consisting of nickel alloys containing Mo, Cu and/or Cr, Ti, Mo, W, Al, Nb, Cr, Zr, Hf, V, Ta and alloys thereof.

9. The assembly according to claim 1, wherein the first coating material is selected from the group consisting of nickel containing proportions of phosphorus, nickel containing proportions of boron, Ni, Cu, Ag, Sn, palladium containing a proportion of phosphorus, Pd, Au.

10. The assembly according to claim 1, wherein the first coating has precisely two layers, wherein the outermost layer is electrolessly deposited gold, and an intermediate layer is NiP.

11. The assembly according to claim 1, wherein the first coating has precisely three layers, wherein the outermost layer is electrolessly deposited gold, an intermediate layer is electrolessly deposited NiP, and a further intermediate layer is palladium-phosphorus.

12. A method for producing an assembly according to claim 1, comprising the steps of
supplying an electric conductor which has a first metal material on its surface or which consists of the first metal material and supplying a main body having an opening which has a second metal material on its surface or consists of the second metal material, or supplying a main body having an opening which has a first metal material on its surface or consists of the first metal material, and supplying an electric conductor which has a second metal material on its surface or consists of the second metal material,
supplying a fixing material blank,
inserting the electric conductor and the fixing material blank into the opening,
embedding the electric conductor and forming the fixing material by means of a temperature treatment in order to obtain an unfinished assembly,
electroless deposition of a layer of a first coating material on exposed surfaces of the electric conductor or on exposed surfaces of the main body by dipping the unfinished assembly into a coating solution,
optionally electroless deposition of one or more further layers on the electric conductor or on the main body by dipping the unfinished assembly into one or more further coating solutions.
